(19) United States
(12) Patent Application Publication
(10) Pub. No.: US 2017/0373071 A1
(43) Pub. Date: Dec. 28, 2017

(54) VERTICAL CHANNEL TRANSISTOR-BASED SEMICONDUCTOR STRUCTURE

(71) Applicant: GLOBALFOUNDRIES Inc., Grand Cayman (KY)

(72) Inventors: Kwan-Yong LIM, Niskayuna, NY (US); Motoi ICHIHASHI, Sunnyvale, CA (US); Youngtag WOO, San Ramon, CA (US); Deepak NAYAK, Fremont, CA (US)

(73) Assignee: GLOBALFOUNDRIES Inc., Grand Cayman (KY)

(21) Appl. No.: 15/193,902

(22) Filed: Jun. 27, 2016

(51) Int. Cl. H01L 27/11; H01L 29/423; H01L 27/092; H01L 21/8238; H01L 23/528; H01L 29/78; H01L 29/417

(52) U.S. Cl. CPC H01L 27/1104; H01L 29/7827; H01L 29/42372; H01L 29/42364; H01L 29/41741; H01L 21/823828; H01L 23/528; H01L 21/823885; H01L 21/823871; H01L 27/092

(57) ABSTRACT

A semiconductor memory structure includes adjacent cross-sectionally rectangular-shaped bottom source and drain electrodes, the electrodes including n-type electrode(s) and p-type electrode(s), and vertical channel transistors on one or more of the n-type electrode(s) and one or more of the p-type electrode(s); each vertical channel transistor including a vertical channel and a gate electrode wrapped therearound, some of the transistors including pull-up transistors. The semiconductor memory structure further includes a routing gate electrode for each gate electrode, and a shared contact having at least two parts, each part situated over the routing gate electrodes for the pull-up transistors. A unit semiconductor memory cell, the semiconductor memory structure and a corresponding method of forming the memory structure are also provided.

### BACKGROUND OF THE INVENTION

### Technical Field

The present invention generally relates to transistor-based semiconductor devices. More particularly, the present invention relates to vertical channel transistor-based semiconductor memory structures.

### Background Information

As semiconductor devices continue to scale down, the use of lithography has become untenable due to the resolution limits of conventional lithographic equipment. At the same time, companies want to continue to use existing lithography equipment. In the past, the design of semiconductor structures went from planar to three-dimensional, which solved the issues of the time, but the time has come again for a new design.

Thus, a need exists for a lithography friendly design, while also having a design that can be downscaled.

### SUMMARY OF THE INVENTION

The shortcomings of the prior art are overcome and additional advantages are provided through the provision, in one aspect, of a semiconductor structure. The semiconductor structure includes a plurality of vertical channel transistors that are horizontally adjacent, each vertical channel transistor including a non-shared bottom source/drain electrode, a vertical channel on the non-shared bottom source/drain electrode, a gate wrapped around the vertical channel, and a shared top source/drain electrode on the vertical channel and gate. The plurality of transistors are grouped according to each shared top source/drain electrode.

In accordance with another aspect, a unit semiconductor memory cell is provided. The unit semiconductor memory cell includes a plurality of non-shared bottom source/drain electrodes, each of the plurality of non-shared bottom source/drain electrodes being one of n-type and p-type. The unit semiconductor memory cell further includes a plurality of vertical channels over at least some of the plurality of non-shared bottom source/drain electrodes, the plurality of vertical channels grouped into at least two sets, each of the at least two sets including a vertical channel for a pull-up transistor, at least one vertical channel for a pull-down transistor, at least one vertical channel for a pass-gate transistor, a wrap-around gate surrounding each vertical channel, a routing gate electrode for each wrap-around gate, and a shared top source/drain electrode for each of the at least two sets.

In accordance with yet another aspect, a method of fabricating a semiconductor memory cell is provided. The method includes forming a plurality of bottom source/drain electrodes, the plurality of bottom source/drain electrodes being non-shared, horizontally adjacent one another, and including at least one n-type electrode and at least one p-type electrode. The method further includes forming a plurality of vertical channels on one or more of the at least one n-type electrode and one or more of the at least one p-type electrode, a gate electrode wrapped around each vertical channel, at least some of the plurality of vertical channels for pull-up transistors, forming a routing gate electrode for each gate electrode, and forming a shared top source/drain contact on at least two sets of vertical channels and associated gate electrodes.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is an elevational view of one example of a semiconductor memory structure at an intermediate stage of fabrication, the semiconductor memory structure including eight adjacent rectangular-shaped bottom source/drain electrodes, four n-type and four p-type, transistors in process having vertical channels and a circular cross-sectional shape source/drain electrodes, and being situated on the eight adjacent rectangular-shaped source/drain electrodes, the vertical channels being encapsulated by a spacer (hard or soft material, e.g., silicon nitride or silicon dioxide, respectively) and a wrap-around gate, the transistors in process separated into two sets, each set including a pull-up transistor in process, a pull-down transistor in process, and a pass gate transistor in process, the semiconductor memory structure being a unit memory cell, in accordance with one or more aspects of the present invention.

FIG. 2 depicts one example of the structure of FIG. 1 after forming routing electrical connections among the gates as shown, in accordance with one or more aspects of the present invention.

FIG. 3 depicts one example of the structure of FIG. 2 after formation of a cross-coupled (i.e., shared) contact having two parts on the connections to the pull-up transistors, in accordance with one or more aspects of the present invention.

FIG. 4 depicts one example of the structure of FIG. 3 after forming a top electrode for each set of transistors (FIG. 1), and forming a hard mask for a subsequent self-aligned contact process over the top electrodes, respectively, in accordance with one or more aspects of the present invention.

FIG. 5 depicts one example of the structure of FIG. 4 after forming spacers around outer sides of the top electrode/hard mask pairs (e.g., FIG. 4, top electrode and hard mask), in accordance with one or more aspects of the present invention.

FIG. 6 depicts one example of the structure of FIG. 5 after forming word line contacts, and forming contacts to the bottom S/D electrodes (FIG. 1), respectively, in accordance with one or more aspects of the present invention.

FIG. 7 depicts one example of the structure of FIG. 6 after forming landing pads for subsequent word line and bit line formation, respectively, in accordance with one or more aspects of the present invention.

FIG. 8 depicts one example of the structure of FIG. 7 after forming bit lines, as well as forming Vss contacts, all including intermediate connections, in accordance with one or more aspects of the present invention.

FIG. 9 depicts a top-down view, a transistor connectivity view and a schematic view, all corresponding to the structure of FIG. 8, in accordance with one or more aspects of the present invention.

FIG. 10 is a perspective view of one example of a simplified vertical transistor for a memory device (e.g., SRAM), with an accompanying top-down view and corresponding schematic, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus five percent of the value. Also, unless otherwise specified, a given aspect of semiconductor fabrication described herein may be accomplished using conventional processes and techniques, where part of a method, and may include conventional materials appropriate for the circumstances, where a semiconductor structure is described.

Reference is made below to the drawings, which are not drawn to scale for ease of understanding, wherein the same reference numbers are used throughout different figures to designate the same or similar components.

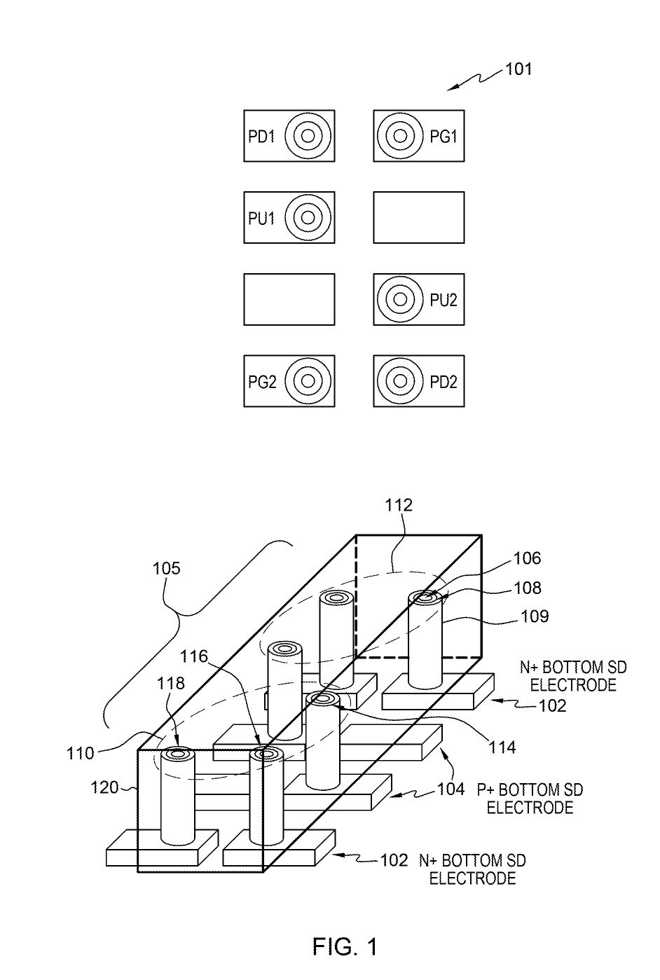

FIG. 1 is an elevational view of one example of a semiconductor memory structure 100 at an intermediate stage of fabrication, the semiconductor memory structure including eight adjacent rectangular-shaped bottom source/drain electrodes, four n-type and four p-type (e.g., n-type 102 and p-type 104), transistors in process 105 having vertical channels 106 and a circular cross-sectional shape, and being situated on the eight adjacent rectangular-shaped source/drain electrodes, the vertical channels being encapsulated by a spacer 108 (hard or soft material, e.g., silicon nitride or silicon dioxide, respectively) and a wrap-around gate 109, the transistors in process separated into two sets 110, 112, each set including a pull-up transistor in process (e.g., pull-up transistor in process 114), a pull-down transistor in process (e.g., pull-down transistor in process 116) and a pass gate transistor in process (e.g., pass gate transistor in process 118), the semiconductor memory structure being a unit memory cell 120, in accordance with one or more aspects of the present invention.

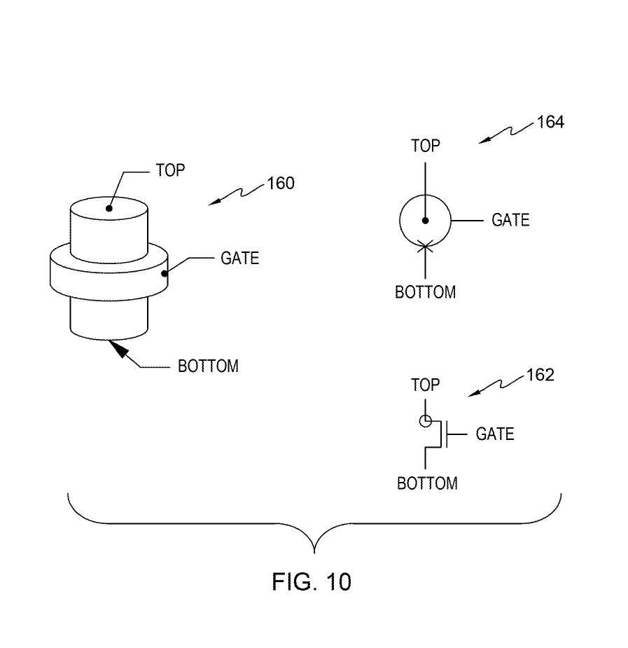

FIG. 10 is a perspective view of one example of a simplified vertical transistor 160 for a memory device (e.g., SRAM), for example, any of the vertical transistors of FIG. 1, with accompanying top-down view 164 and corresponding schematic 162, in accordance with one or more aspects of the present invention.

The starting structure may be conventionally fabricated, for example, using known processes and techniques. Further, unless noted otherwise, conventional processes and techniques may be used to achieve individual steps of the fabrication process of the present invention. However, although only a single memory cell is shown for simplicity, it will be understood that, in practice, many such structures are typically included on the same substrate (e.g., a bulk substrate).

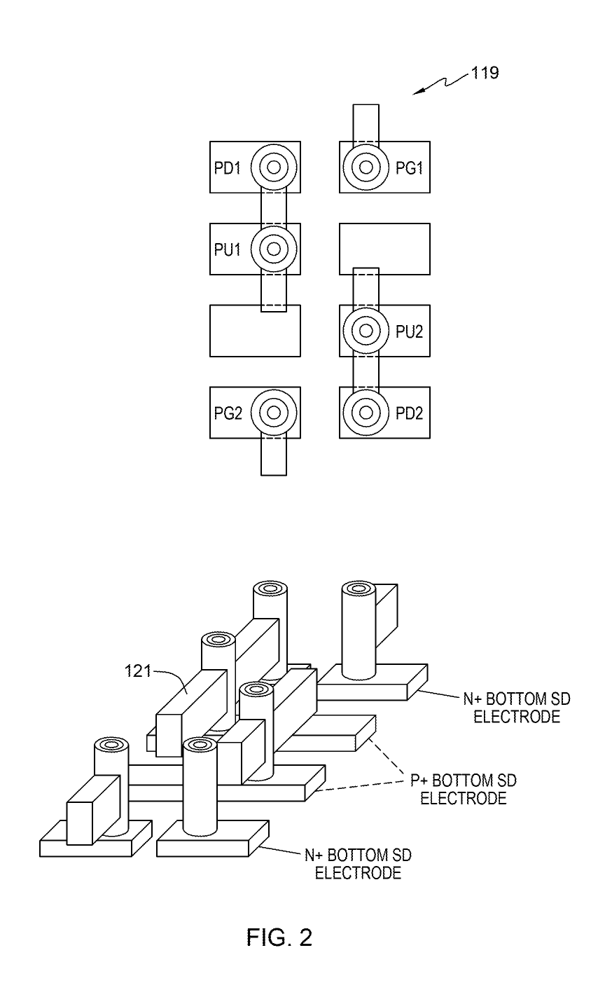

FIG. 2 depicts one example of the structure of FIG. 1 after forming routing electrical connections (e.g., routing connection 121) among the gates as shown, in accordance with one or more aspects of the present invention.

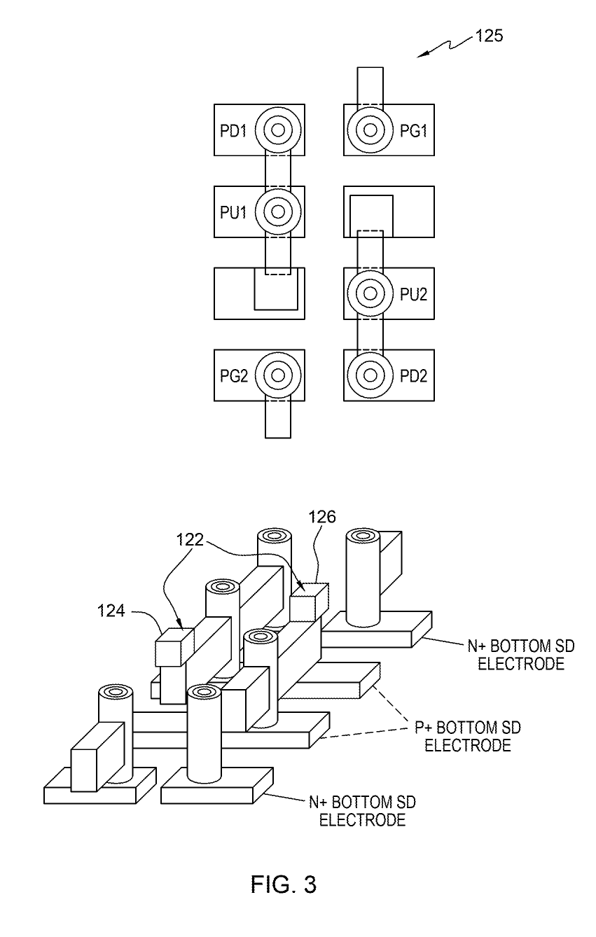

FIG. 3 depicts one example of the structure of FIG. 2 after formation of a cross-coupled (i.e., shared) contact 122 having two parts 124 and 126 on the connections to the pull-up transistors, in accordance with one or more aspects of the present invention.

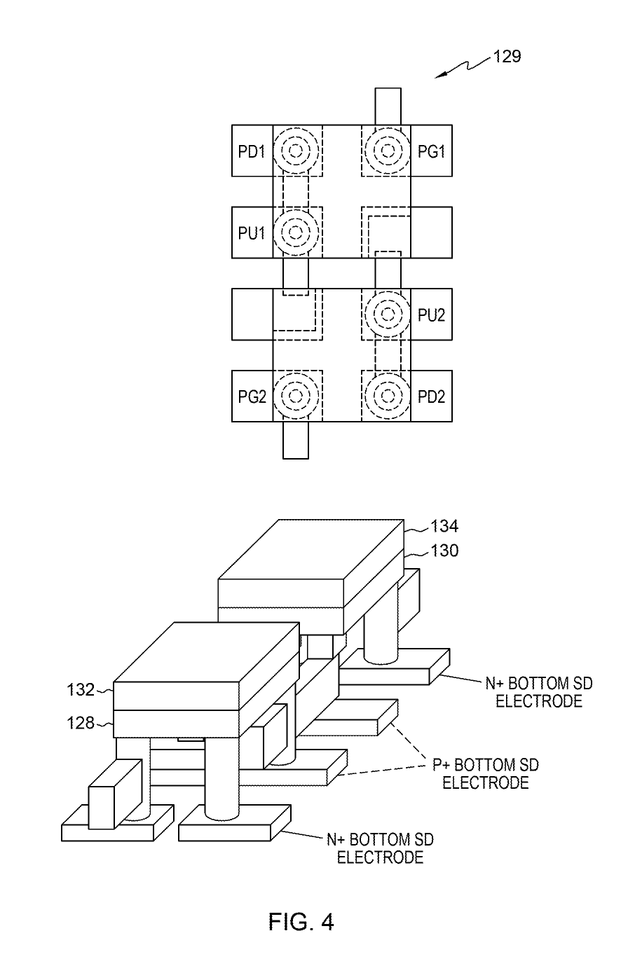

FIG. 4 depicts one example of the structure of FIG. 3 after forming a top electrode 128 and 130 for each set of transistors (FIG. 1, 110 and 112), and forming a hard mask for a subsequent self-aligned contact process 132 and 134 over the top electrodes 128 and 130, respectively, in accordance with one or more aspects of the present invention.

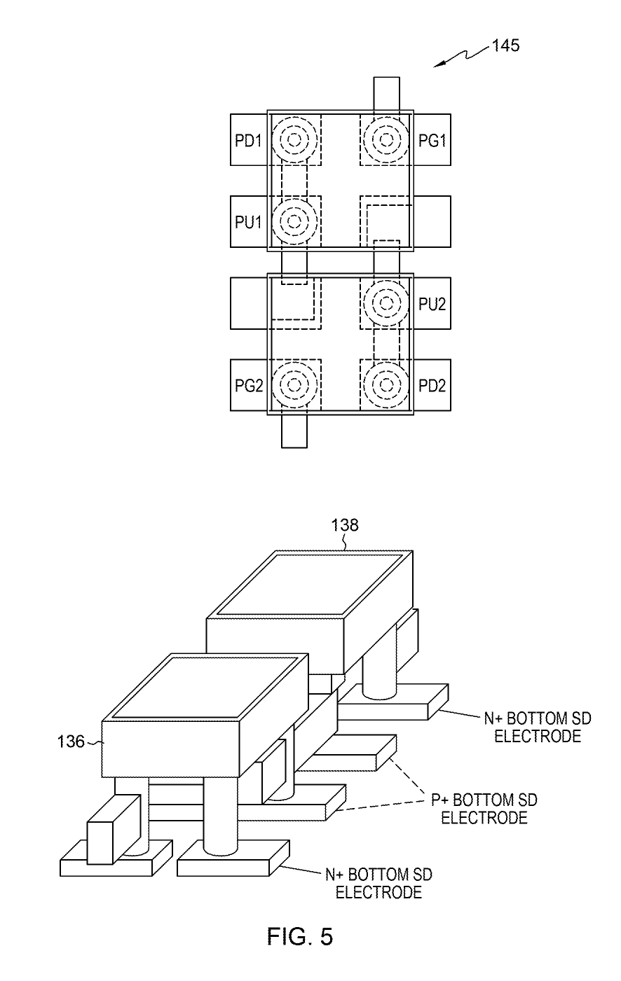

FIG. 5 depicts one example of the structure of FIG. 4 after forming spacers 136 and 138 around outer sides of the top electrode/hard mask pairs (e.g., FIG. 4, top electrode 128 and hard mask 132), in accordance with one or more aspects of the present invention.

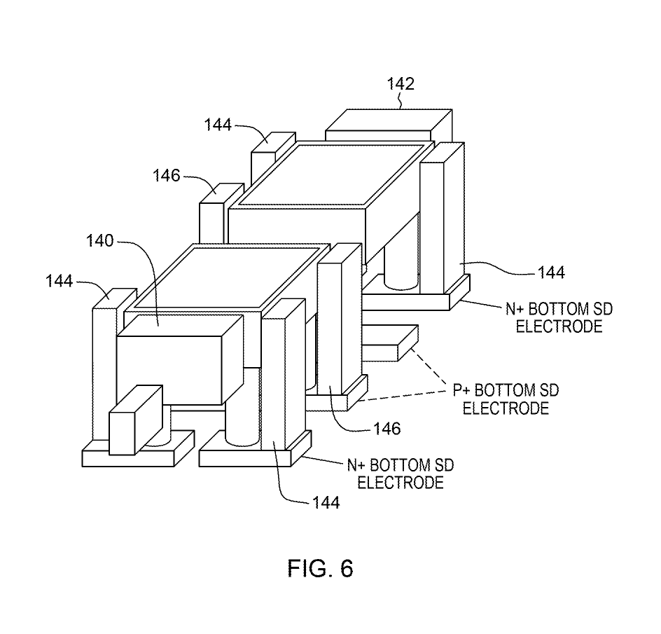

FIG. 6 depicts one example of the structure of FIG. 5 after forming word line contacts 140 and 142, and forming contacts 144 and 146 to bottom S/D electrodes (FIG. 1, 102 and 104), respectively, in accordance with one or more aspects of the present invention.

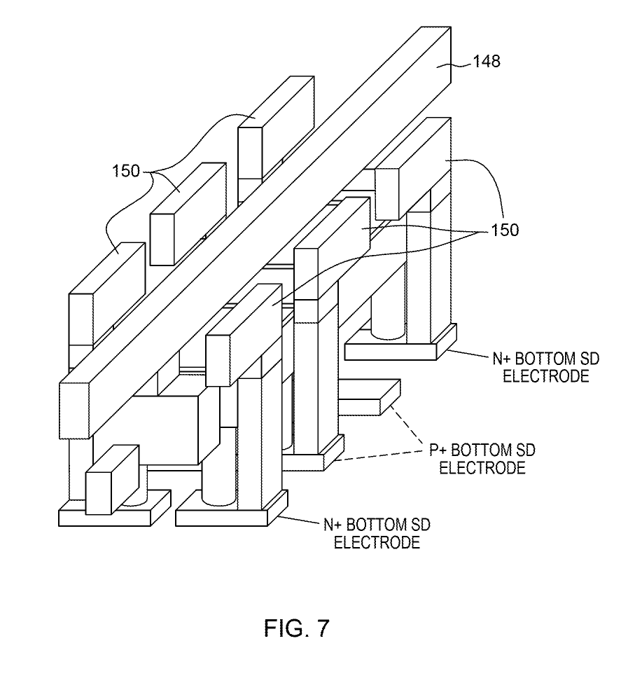

FIG. 7 depicts one example of the structure of FIG. 6 after forming landing pads 148 and 150 for subsequent word line and bit line formation, respectively, in accordance with one or more aspects of the present invention.

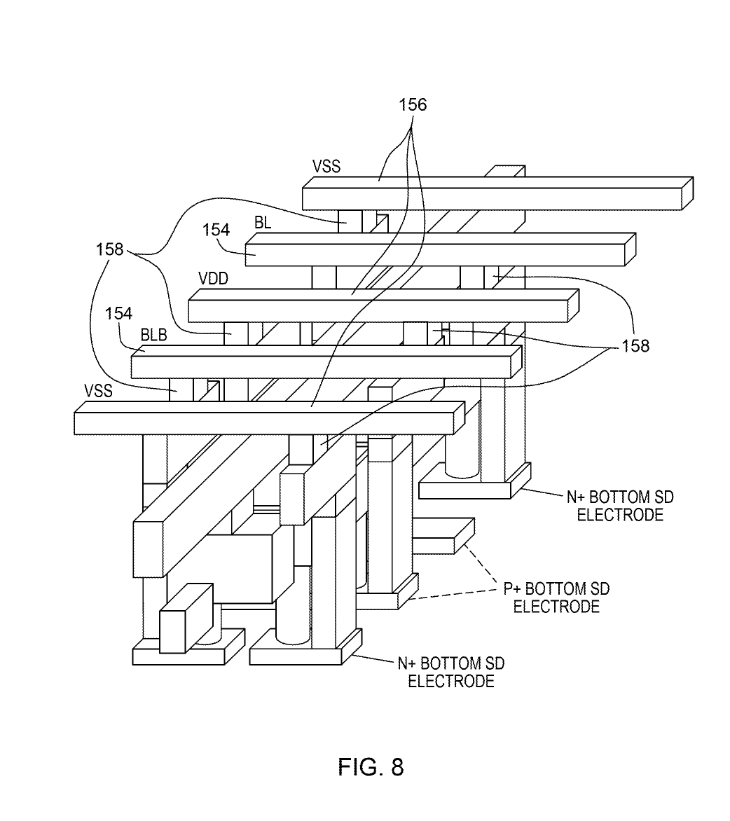

FIG. 8 depicts one example of the structure of FIG. 7 after forming bit lines 152 and 154, as well as forming Vss contacts 156, all including intermediate connections 158, in accordance with one or more aspects of the present invention.

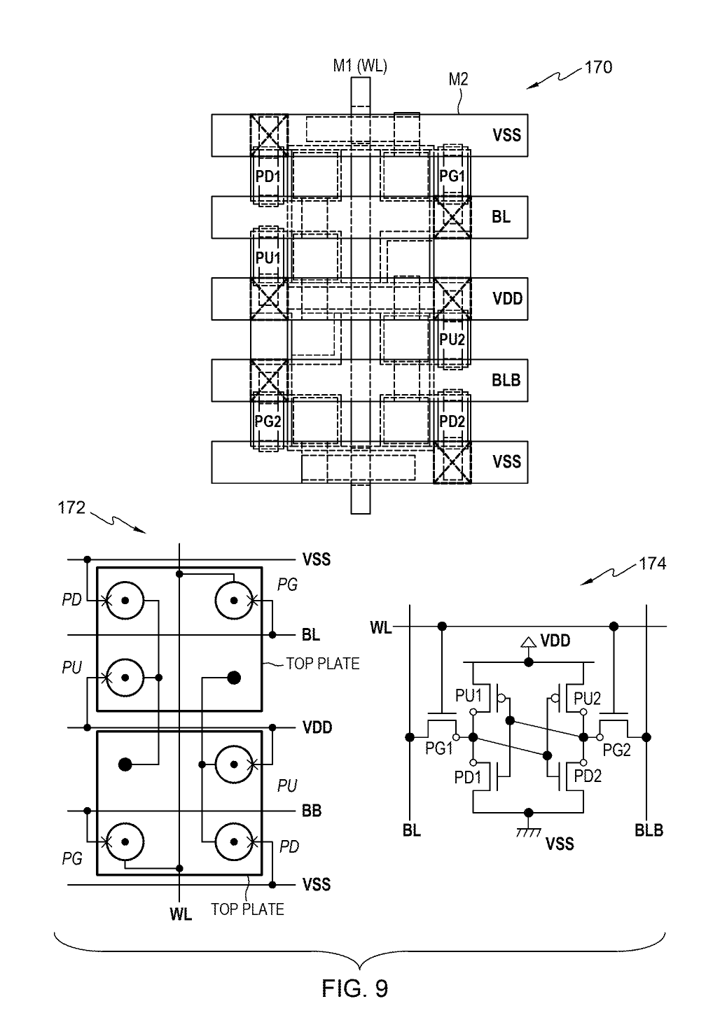

FIG. 9 depicts top-down view 170, transistor connectivity view 172 and schematic view 174, all corresponding to the structure of FIG. 8, in accordance with one or more aspects of the present invention.

In a first aspect, disclosed above is a semiconductor structure. The semiconductor structure includes vertical channel transistors that are horizontally adjacent, each vertical channel transistor including a non-shared bottom source/drain electrode. The semiconductor structure further includes a vertical channel on the non-shared bottom source/drain electrode, a gate wrapped around the vertical channel, and a shared top source/drain electrode on the vertical channel and gate. The transistors are grouped according to each shared top source/drain electrode.

In one example, each of the vertical channel transistors may further include, for example, a gate dielectric layer wrapped around the vertical channel and situated between the vertical channel and the gate electrode.

In one example, the vertical channel transistors of the semiconductor structure of the first aspect may be, for example, grouped into at least two sets, each of the at least two sets including a pull-up transistor, pull-down transistor(s), and pass-gate transistor(s).

In one example, the semiconductor structure may further include, for example, routing gate electrode(s) for each gate. In one example, the semiconductor structure may further include, for example, a cross-coupled contact having at least two parts, each of the at least two parts being situated on a routing gate electrode for a pull-up transistor of one of the at least two sets. In one example, the semiconductor structure may further include, for example, a hard mask over each shared top source/drain electrode. In one example, the semiconductor structure may further include, for example, a spacer wrapped around sides of each shared top source/drain electrode and associated hard mask. In one example, the semiconductor structure may further include, for example, a word line contact for each of the at least two sets. In one example, the semiconductor structure may further include, for example, a bottom electrode contact for each non-shared bottom source/drain electrode. In one example, the semiconductor structure may further include, for example, a word line landing pad over the word line contact for each of the at least two sets. In one example, the semiconductor structure may further include, for example, a separate bit line landing pad over each bottom electrode contact.

In a second aspect, disclosed above is a unit semiconductor memory cell. The unit semiconductor memory cell includes non-shared bottom source/drain electrodes, each of the non-shared bottom source/drain electrodes being one of n-type and p-type. The unit semiconductor memory cell further includes vertical channels over at least some of the non-shared bottom source/drain electrodes, the vertical channels grouped into at least two sets, each of the at least two sets including a vertical channel for a pull-up transistor, vertical channel(s) for pull-down transistor(s), vertical channel(s) for pass-gate transistor(s), a wrap-around gate surrounding each vertical channel, a routing gate electrode for each wrap-around gate, and a shared top source/drain electrode for each of the at least two sets.

In one example, the unit semiconductor memory cell may further include, for example, a hard mask over each shared top source/drain electrode. In one example, the unit semiconductor memory cell may further include, for example, a spacer wrapped around sides of each shared top source/drain electrode and associated hard mask.

In one example, the unit semiconductor memory cell of the second aspect may further include, for example, metallization layer(s) thereover.

In one example, the unit semiconductor memory cell of the second aspect may further include, for example, a cross-coupled contact having at least two parts, each of the at least two parts on a routing gate electrode for each pull-up transistor.

In a third aspect, disclosed above is a method. The method includes forming bottom source/drain electrodes, the bottom source/drain electrodes being non-shared, horizontally adjacent one another, and including n-type electrode(s) and p-type electrode(s). The method further includes forming vertical channels on the n-type electrode(s) and the p-type electrode(s), a gate electrode wrapped around each vertical channel, at least some of the vertical channels for pull-up transistors, forming a routing gate electrode for each gate electrode, and forming a shared top source/drain contact on at least two sets of vertical channels and associated gate electrodes.

In one example, the method may further include, for example, a shared contact having at least two parts, each part situated over the routing gate electrodes for the pull-up transistors.

In one example, the method of the third aspect may further include, for example, for each of at least two sets of vertical channels, forming a pull-up transistor, forming pull-down transistor(s), and forming pass-gate transistor(s).

In one example, the method may further include, for example, forming a hard mask over each top electrode, and forming a spacer wrapped around sides of each top electrode and associated hard mask.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A semiconductor structure, comprising:
a plurality of vertical channel transistors that are horizontally adjacent, each vertical channel transistor comprising:
a non-shared bottom source/drain electrode;
a vertical channel on the non-shared bottom source/drain electrode;
a gate wrapped around the vertical channel;
a shared top source/drain electrode on the vertical channel and gate; and
a hard mask over each shared top source/drain electrode;
wherein the plurality of transistors are grouped according to each shared top source/drain electrode.

2. The semiconductor structure of claim 1, wherein each of the plurality of vertical channel transistors further comprises a gate dielectric layer wrapped around the vertical channel and situated between the vertical channel and the gate electrode.

3. The semiconductor structure of claim 1, wherein the plurality of vertical channel transistors are grouped into at least two sets, each of the at least two sets comprising:
a pull-up transistor;
at least one pull-down transistor; and
at least one pass-gate transistor.

4. The semiconductor structure of claim 3, further comprising at least one routing gate electrode for each gate.

5. The semiconductor structure of claim 4, further comprising a cross-coupled contact having at least two parts, each of the at least two parts being situated on a routing gate electrode for a pull-up transistor of one of the at least two sets.

6. (canceled)

7. The semiconductor structure of claim 5, further comprising a spacer wrapped around sides of each shared top source/drain electrode and associated hard mask.

8. The semiconductor structure of claim 7, further comprising a word line contact for each of the at least two sets.

9. The semiconductor structure of claim 8, further comprising a bottom electrode contact for each non-shared bottom source/drain electrode.

10. The semiconductor structure of claim 9, further comprising a word line landing pad over the word line contact for each of the at least two sets.

11. The semiconductor structure of claim 10, further comprising a separate bit line landing pad over each bottom electrode contact.

12. A unit semiconductor memory cell, comprising:
a plurality of non-shared bottom source/drain electrodes, each of the plurality of non-shared bottom source/drain electrodes being one of n-type and p-type;
a plurality of vertical channels over at least some of the plurality of non-shared bottom source/drain electrodes, the plurality of vertical channels grouped into at least two sets, each of the at least two sets comprising:
a vertical channel for a pull-up transistor;
at least one vertical channel for a pull-down transistor; and
at least one vertical channel for a pass-gate transistor;
a wrap-around gate surrounding each vertical channel;
a routing gate electrode for each wrap-around gate;
a shared top source/drain electrode for each of the at least two sets; and
a hard mask over each shared top source/drain electrode.

13. (canceled)

14. The unit semiconductor memory cell of claim 13, further comprising a spacer wrapped around sides of each shared top source/drain electrode and associated hard mask.

15. The unit semiconductor memory cell of claim 12, further comprising at least one metallization layer over the unit semiconductor memory cell.

16. The unit semiconductor memory cell of claim 12, further comprising a cross-coupled contact having at least two parts, each of the at least two parts on a routing gate electrode for each pull-up transistor.

17. A method, comprising:
forming a plurality of bottom source/drain electrodes, the plurality of bottom source/drain electrodes being non-shared, horizontally adjacent one another, and comprising at least one n-type electrode and at least one p-type electrode;
forming a plurality of vertical channels on one or more of the at least one n-type electrode and one or more of the at least one p-type electrode;
a gate electrode wrapped around each vertical channel, at least some of the plurality of vertical channels for pull-up transistors;
forming a routing gate electrode for each gate electrode;
forming a shared top source/drain contact on at least two sets of vertical channels and associated gate electrodes; and
forming a hard mask over each shared top source/drain contact.

18. The method of claim 17, further comprising a shared contact having at least two parts, each part situated over the routing gate electrodes for the pull-up transistors.

19. The method of claim 17, further comprising, for each of at least two sets of vertical channels:
forming a pull-up transistor;
forming at least one pull-down transistor; and
forming at least one pass-gate transistor.

20. The method of claim 19, further comprising
forming a spacer wrapped around sides of each top source/drain contact and associated hard mask.
